(19) United States
(12) Patent Application Publication
(10) Pub. No.: US 2025/0140765 A1
(43) Pub. Date: May 1, 2025

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Yi-Min FU, Taichung City (TW); Chi-Ching HO, Taichung City (TW); Chao-Chiang PU, Taichung City (TW); Yu-Po WANG, Taichung City (TW)

(21) Appl. No.: 18/631,682

(22) Filed: Apr. 10, 2024

(30) Foreign Application Priority Data
Nov. 1, 2023 (TW) 112142059

(51) Int. Cl. H01L 25/16; H01L 23/00; H01L 23/367; H01L 23/538; H01L 25/00; H01L 25/18

(52) U.S. Cl. CPC H01L 25/167; H01L 23/367; H01L 23/5389; H01L 24/24; H01L 24/82; H01L 25/18; H01L 25/50; H01L 24/16; H01L 24/32; H01L 24/73; H01L 2224/16227; H01L 2224/24137; H01L 2224/24195; H01L 2224/245; H01L 2224/32225; H01L 2224/73204; H01L 2224/82005; H01L 2924/01029; H01L 2924/1425; H01L 2924/1426

(57) ABSTRACT

An electronic package and a manufacturing method thereof are provided, in which a plurality of photonic integrated circuit chips and an auxiliary electronic element are separately configured on a package module to shorten the transmission distance of the optical signal. Therefore, the signal transmission rate of a circuit structure can be increased, thereby improving the overall operating performance of the electronic package.

### CROSS-REFERENCE TO RELATED APPLICATIONS

The present application is based upon and claims the right of priority to TW patent application No. 112142059, filed Nov. 1, 2023, the disclosure of which is hereby incorporated by reference herein in its entirety for all purposes.

### BACKGROUND

### 1. Technical Field

The present disclosure relates to a semiconductor packaging process, and more particularly, to an electronic package having multiple functions and a manufacturing method thereof.

### 2. Description of Related Art

With the vigorous development of the electronics industry, electronic products are gradually developing towards multi-function and high performance. In order to meet the packaging needs of miniaturization of electronic packages, wafer-level packaging (WLP) technology was developed.

FIG. 1A to FIG. 1E are schematic cross-sectional views illustrating a manufacturing method of a conventional semiconductor package 1 using wafer-level packaging technology.

As shown in FIG. 1A, a thermal release tape 100 is formed on a carrier 10.

Next, a plurality of communication chips 11 are placed on the thermal release tape 100, and each of the communication chips 11 has an active surface 11a and an inactive surface 11b opposing the active surface 11a, wherein the active surface 11a has a plurality of electrode pads 110, and the active surface 11a is adhered onto the thermal release tape 100.

As shown in FIG. 1B, an encapsulation colloid 14 is formed on the thermal release tape 100 to cover the communication chips 11.

As shown in FIG. 1C, the encapsulation colloid 14 is baked to harden the thermal release tape 100, and then the thermal release tape 100 and the carrier 10 are removed to expose the active surfaces 11a of the communication chips 11.

As shown in FIG. 1D, a circuit structure 16 is formed on the encapsulation colloid 14 and the active surfaces 11a of the communication chips 11, so that the circuit structure 16 is electrically connected to the electrode pads 110. Then, an insulating protective layer 18 is formed on the circuit structure 16, and parts of a surface of the circuit structure 16 are exposed from the insulating protective layer 18 for bonding to conductive elements 17 such as solder balls.

As shown in FIG. 1E, a singulation process is performed along a cutting path L as shown in FIG. 1D to obtain a plurality of the semiconductor packages 1.

However, as the amount of data transmitted by data transmission networks increases significantly, data transmission equipment must meet the increasing bandwidth requirements. The disadvantages of using copper materials as data channels (such as the lines of the circuit structure 16) are becoming more and more noticeable. Therefore, optical fiber communication is becoming more and more important in communication equipment for transmitting large amounts of data at the current stage, and conventional structures are no longer sufficient for optical communication.

Therefore, the industry is actively developing packaging structures that can be used for large amounts of data transmission to meet the needs of today's applications in various fields. In fact, this is a technical problem that all walks of life urgently want to solve.

### SUMMARY

In view of the various deficiencies of the prior art, the present disclosure provides an electronic package, which comprises: a cladding layer having a first surface, a second surface opposing the first surface, and side surfaces adjacent to the first surface and the second surface; at least one first electronic element embedded in the cladding layer; a plurality of conductive pillars embedded in the cladding layer; a circuit structure formed on the first surface of the cladding layer and electrically connected to the plurality of conductive pillars and the at least one first electronic element; an auxiliary electronic element disposed on and connected to the circuit structure; and a plurality of second electronic elements disposed on and electrically connected to the circuit structure, wherein the plurality of second electronic elements are photonic integrated circuit chips.

The present disclosure further comprises a method of manufacturing an electronic package, the method comprises: disposing a plurality of conductive pillars and at least one first electronic element on a carrier board; forming a cladding layer on the carrier board to cover the at least one first electronic element and the plurality of conductive pillars, wherein the cladding layer has a first surface and a second surface opposing the first surface, end surfaces of the plurality of conductive pillars are exposed from the first surface of the cladding layer, and the second surface of the cladding layer is bonded onto the carrier board; forming a circuit structure on the first surface of the cladding layer, wherein the circuit structure is electrically connected to the plurality of conductive pillars and the at least one first electronic element, and the cladding layer is formed with side surfaces adjacent to the first surface and the second surface; disposing an auxiliary electronic element and a plurality of second electronic elements on the circuit structure, wherein the auxiliary electronic element and the plurality of second electronic elements are connected to the circuit structure, wherein the plurality of second electronic elements are photonic integrated circuit chips; and removing the carrier board.

In the aforementioned electronic package and method, the at least one first electronic element is bonded and electrically connected to a plurality of conductors. For example, the plurality of conductors are covered by a protective film and embedded in the cladding layer, and the plurality of conductors are electrically connected to the circuit structure.

In the aforementioned electronic package and method, the at least one first electronic element is surrounded by the plurality of conductive pillars.

In the aforementioned electronic package and method, the auxiliary electronic element is a switch or a semiconductor chip for heat dissipation.

In the aforementioned electronic package and method, the plurality of second electronic elements protrude from the side surfaces of the cladding layer.

In the aforementioned electronic package and method, the plurality of second electronic elements are externally connected to electrical connectors.

In the aforementioned electronic package and method, the present disclosure further comprises forming a circuit portion on the second surface of the cladding layer, and electrically connecting the circuit portion to the plurality of conductive pillars. Further, the present disclosure may comprises forming a plurality of conductive elements on the circuit portion.

In the aforementioned electronic package and method, the present disclosure further comprises disposing a carrier structure on the second surface of the cladding layer.

As can be seen from the above, in the electronic package and the manufacturing method thereof of the present disclosure, the photonic integrated circuit chips and the auxiliary electronic element are integrated onto the same package module to shorten the distance between the switch and the optical/electrical signal elements. Therefore, compared to the prior art, the present disclosure can increase the signal transmission rate of the circuit structure and reduce the latency, thereby improving the overall operating performance of the electronic package.

Furthermore, the manufacturing method of the present disclosure can be implemented using existing semiconductor packaging processes, so there is no need to develop a special process or purchase equipment with special specifications. Therefore, the manufacturing method of the present disclosure can effectively reduce the production cost of the electronic package.

### BRIEF DESCRIPTION OF THE DRAWINGS

FIG. 1A to FIG. 1E are schematic cross-sectional views illustrating a manufacturing method of a conventional semiconductor package.

FIG. 2A to FIG. 2E are schematic cross-sectional views illustrating a manufacturing method of an electronic package according to the present disclosure.

FIG. 3 is a schematic cross-sectional view of the subsequent process of FIG. 2E.

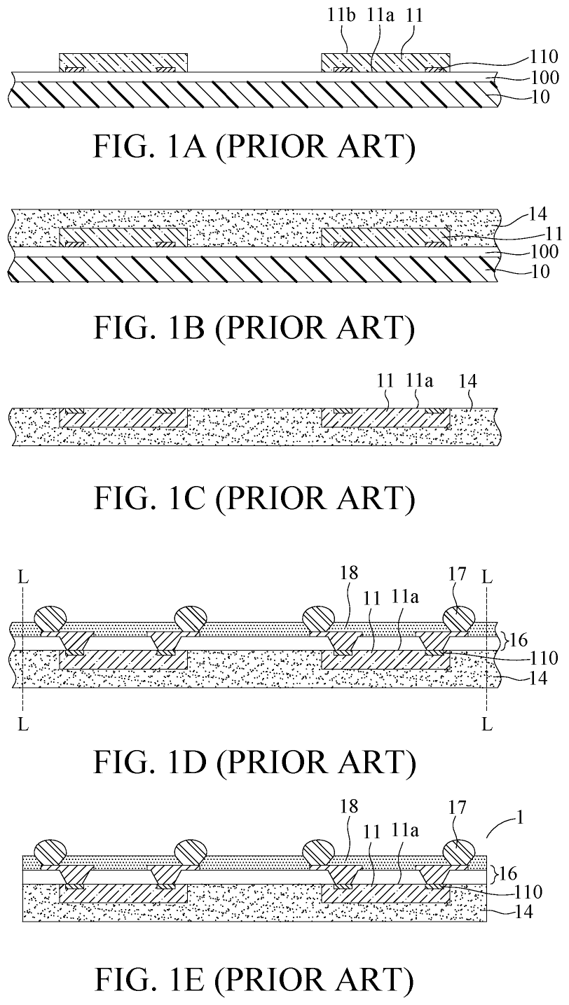

### DETAILED DESCRIPTION

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “upper,” “first,” “second,” “one,” “a” and the like used herein are merely used for clear explanation rather than limiting the practicable scope of the present disclosure, and thus, alterations or adjustments of the relative relationships thereof without essentially altering the technical contents should still be considered in the practicable scope of the present disclosure.

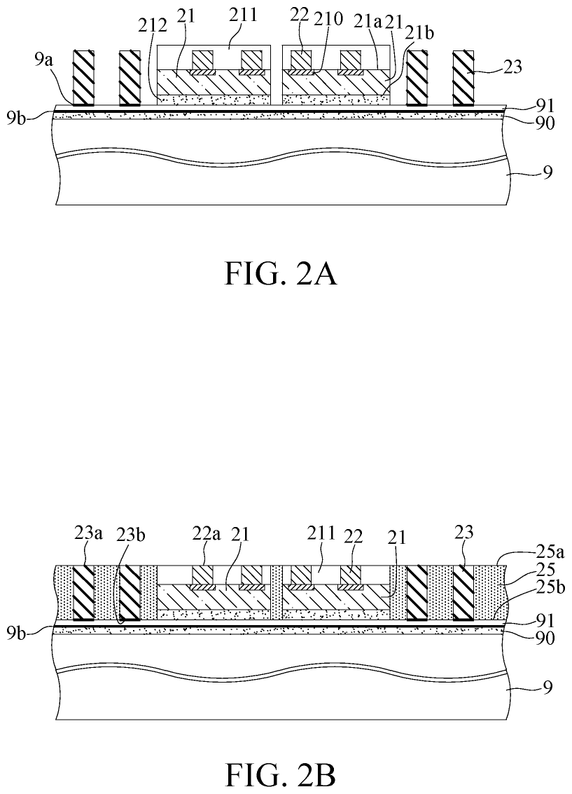

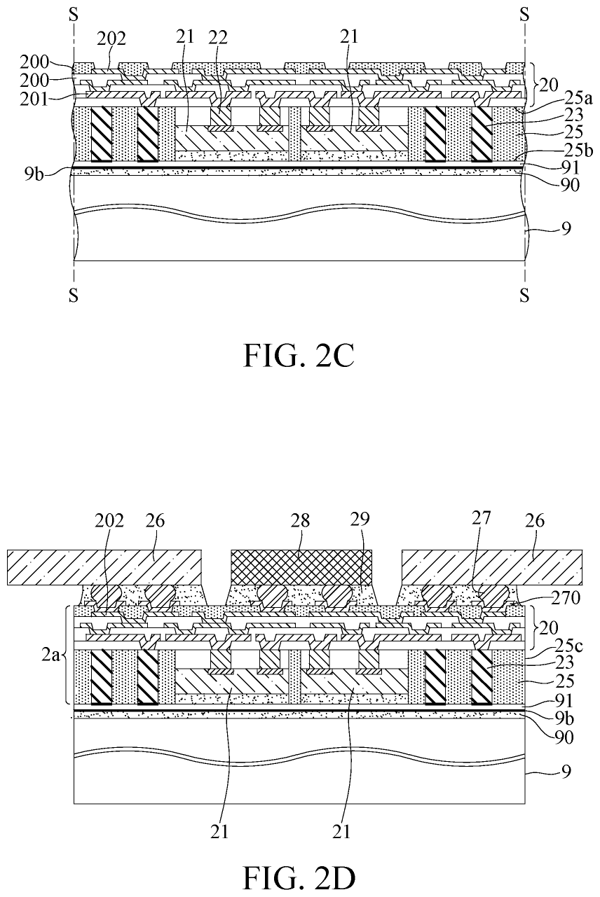

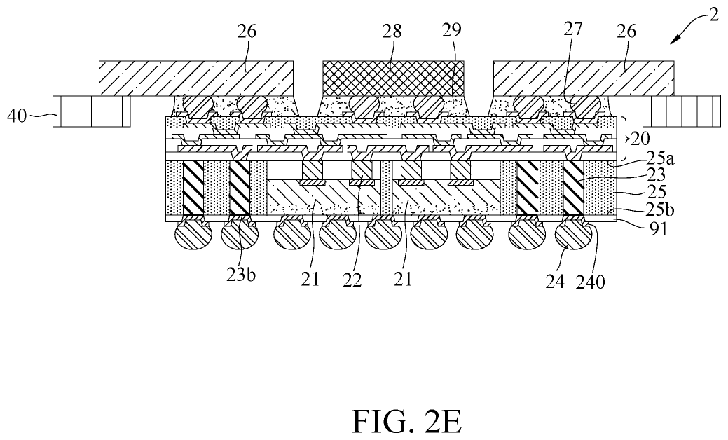

FIG. 2A to FIG. 2E are schematic cross-sectional views illustrating a manufacturing method of an electronic package 2 according to the present disclosure.

As shown in FIG. 2A, a plurality of conductive pillars 23 are formed on a carrier board 9, and at least one first electronic element 21 is disposed on the carrier board 9 (this embodiment shows two first electronic elements 21), wherein the first electronic element 21 is bonded and electrically connected to a plurality of conductors 22.

In one embodiment, the carrier board 9 is, for example, a board made of semiconductor material (such as silicon or glass), on which a release layer 90, a metal layer 9b made of such as titanium/copper, an insulating layer 91 made of such as a dielectric material or a solder-resist material, and a seed layer 9a are sequentially formed by, for example, coating, wherein a patterned resist layer (not shown) can be formed on the seed layer 9a, and parts of a surface of the seed layer 9a are exposed from the resist layer, so that the conductive pillars 23 can be formed by electroplating. After the conductive pillars 23 are made, the patterned resist layer and the seed layer 9a underneath are removed, so that the conductive pillars 23 are disposed on the insulating layer 91.

Furthermore, the material for forming the plurality of conductive pillars 23 is a metal material such as copper or a solder material, and the plurality of conductors 22 are spherical conductive members such as solder balls, or cylindrical metal conductive members such as copper pillars, solder bumps, etc., or stud-shaped conductive members made by a wire bonding machine, but the present disclosure is not limited to as such.

In addition, the first electronic element 21 is an active element, a passive element, or a combination of the active element and the passive element, wherein the active element is, for example, a semiconductor chip, and the passive element is, for example, a resistor, a capacitor, or an inductor. In one embodiment, the first electronic element 21 is a semiconductor chip and has an active surface 21a and an inactive surface 21b opposing the active surface 21a, wherein the inactive surface 21b of the first electronic element 21 is adhered onto the insulating layer 91 via a bonding layer 212, the active surface 21a has a plurality of electrode pads 210 and a protective film 211 made of such as a dielectric material, and the conductors 22 are in the protective film 211.

In addition, the first electronic element 21 is such as a driver or a trans impedance amplifier (TIA) to provide the required functions, for example, a chip related to electrical application functions such as driving laser diodes or converting analog signals into digital signals to improve the signal-to-noise ratio (S/N) or other functions. For example, a semiconductor material such as silicon dioxide (SiO₂) can be used to make the required wafer substrate, and an 8-inch wafer process can be carried out with a specification of 130 nanometers (nm) to make the driver or the trans impedance amplifier. Specifically, one of the first electronic elements 21 serves as a trans impedance amplifier (TIA), and the other first electronic element 21 serves as a driver, so that a photocurrent converted by a photodetector is processed by the trans impedance amplifier (the first electronic element 21) and a limiting amplifier. The trans impedance amplifier and the limiting amplifier can convert the photocurrent into a voltage signal with a smaller amplitude, and then the voltage signal is converted into a digital signal via a back-end comparator circuit.

As shown in FIG. 2B, a cladding layer 25 is formed on the insulating layer 91 of the carrier board 9, so that the cladding layer 25 covers the first electronic elements 21, the conductors 22 and the conductive pillars 23, wherein the cladding layer 25 has a first surface 25a and a second surface 25b opposing the first surface 25a, and the protective film 211, end surfaces 22a of the plurality of conductors 22 and end surfaces 23a of the plurality of conductive pillars 23 are exposed from the first surface 25a of the cladding layer 25, and the second surface 25b of the cladding layer 25 is bonded onto the insulating layer 91 of the carrier board 9.

In one embodiment, the cladding layer 25 is made of an insulating material, such as polyimide (PI), dry film, encapsulation colloid such as epoxy resin, or other types of molding compounds. For example, the cladding layer 25 may be formed on the insulating layer 91 by lamination or compression molding.

Furthermore, the first surface 25a of the cladding layer 25 can be flush with the protective film 211, the end surfaces 23a of the plurality of conductive pillars 23, and the end surfaces 22a of the plurality of conductors 22 by a leveling process, so that the end surfaces 23a of the plurality of conductive pillars 23 and the end surfaces 22a of the plurality of conductors 22 are exposed from the first surface 25a of the cladding layer 25. For instance, the leveling process removes a portion of the material of the protective film 211, a portion of the material of each of the conductive pillars 23, a portion of the material of each of the conductors 22 and a portion of the material of the cladding layer 25 by grinding.

In addition, the other end surfaces 23b of the conductive pillars 23 are also flush with the second surface 25b of the cladding layer 25.

As shown in FIG. 2C, a circuit structure 20 is formed on the first surface 25a of the cladding layer 25, and the circuit structure 20 is electrically connected to the plurality of conductive pillars 23 and the plurality of conductors 22.

In one embodiment, the circuit structure 20 includes a plurality of insulating layers 200 and a plurality of redistribution layers (RDLs) 201 formed on the insulating layers 200, wherein the outermost insulating layer 200 can be used as a solder-resist layer, and the outermost redistribution layer 201 is exposed from the solder-resist layer to serve as a plurality of electrical contact pads 202. Alternatively, the circuit structure 20 may only include a single insulating layer 200 and a single redistribution layer 201.

Furthermore, the material for forming the redistribution layer 201 is copper, and the material for forming the insulating layer 200 is a dielectric material such as polybenzoxazole (PBO), polyimide (PI), prepreg (PP), etc., or the material of the outermost insulating layer 200 may be solder-resist material such as solder mask (e.g., green paint), graphite (e.g., ink), etc.

As shown in FIG. 2D, a singulation process is performed along a cutting path S shown in FIG. 2C to obtain a plurality of package modules 2a, so that the cladding layer 25 is formed with side surfaces 25c adjacent to the first surface 25a and the second surface 25b. Then, at least one auxiliary electronic element 28 and a plurality of second electronic elements 26 are further disposed on the circuit structure 20 of the package module 2a, so that the plurality of second electronic elements 26 protrude from the side surfaces 25c of the cladding layer 25 for subsequent external connection to electrical connectors 40 (as shown in FIG. 2E).

In one embodiment, the auxiliary electronic element 28 is a semiconductor chip, such as a switch (a switch die) or a thermal die, and the auxiliary electronic element 28 can be located between the second electronic elements 26 without protruding from the side surfaces 25c of the cladding layer 25.

Furthermore, the second electronic element 26 is an optical chip (a photonic integrated circuit chip), which is a device used to convert optical signals into electrical signals to detect/receive optical signals. For example, the second electronic element 26 can be made of semiconductor materials such as indium phosphide (InP), gallium arsenide (GaAs), silicon germanium (SiGe), or a combination thereof to make the required wafer substrate, and the photonic integrated circuit chip is manufactured using a 4- or 6-inch wafer process with 130 nanometer specifications.

In addition, the auxiliary electronic element 28 and/or the second electronic elements 26 are electrically connected to the plurality of electrical contact pads 202 via a plurality of conductive bumps 27 such as solder bumps, copper bumps, or others. In one embodiment, a plurality of under-bump metallurgy (UBM) layers 270 can be formed on the plurality of electrical contact pads 202 to facilitate bonding with the conductive bumps 27.

In addition, an underfill 29 can be formed between the circuit structure 20 and the auxiliary electronic element 28 and/or the plurality of second electronic elements 26 to cover the conductive bumps 27.

As shown in FIG. 2E, the carrier board 9 and the release layer 90 and the metal layer 9b on the carrier board 9 are removed, and the insulating layer 91 is retained. Then, a circuit portion 240 is formed on the insulating layer 91 to electrically connect the plurality of conductive pillars 23, thereby forming the electronic package 2.

In one embodiment, the insulating layer 91 is formed with a plurality of openings by laser, so that the end surfaces 23b of the conductive pillars 23 and/or parts of the second surface 25b of the cladding layer 25 are exposed from the openings for bonding to the circuit portion 240. For instance, the circuit portion 240 is an under-bump metallurgy (UBM) layer for bonding to a plurality of conductive elements 24 such as solder bumps or solder balls; alternatively, the circuit portion 240 can be formed on the insulating layer 91 by an RDL process so as to bond to the plurality of conductive elements 24 or a UBM layer. It should be understood that there are various aspects of the circuit portion 240, and the present disclosure is not limited to as such.

Furthermore, by providing the carrier board 9 having the insulating layer 91, after the carrier board 9 is removed, the insulating layer 91 can be used to form the circuit portion 240, so there is no need to arrange a dielectric layer. Therefore, the process time and process steps can be saved to achieve the purpose of reducing the process cost.

Therefore, during operation, the driver (one of the first electronic elements 21) drives the second electronic element 26, so that the electrical connector 40 on one of the second electronic elements 26 receives an optical signal from an optical fiber cable (not shown), and then the optical signal is converted into an electrical signal via the first electronic element 21 and the auxiliary electronic element 28.

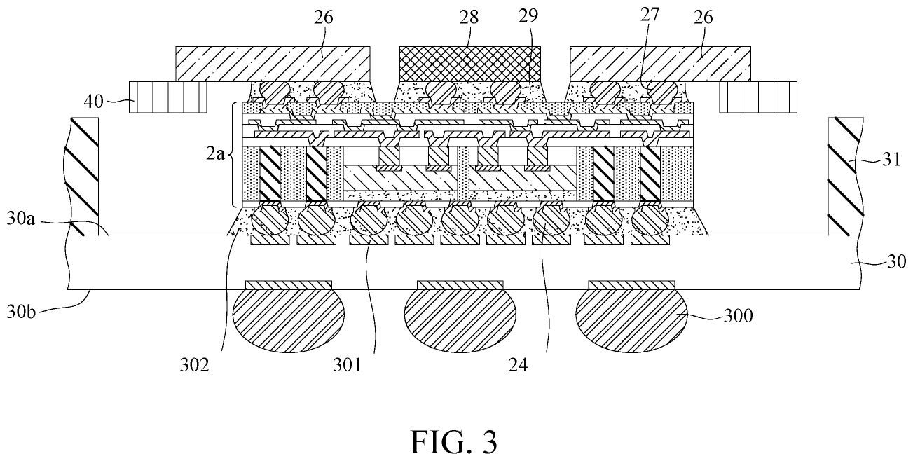

In the subsequent process, as shown in FIG. 3, the electronic package 2 can be disposed on a carrier structure 30 via the conductive elements 24. Furthermore, a ball placement process is performed on the lower side of the carrier structure 30 to form a plurality of solder balls 300, so that in subsequent processes, the carrier structure 30 is disposed on a circuit board (not shown) via the solder balls 300 on the lower side of the carrier structure 30.

In one embodiment, the carrier structure 30 is in the form of a substrate and has an upper surface 30a and a lower surface 30b opposing the upper surface 30a, so that the conductive elements 24 are disposed on the upper surface 30a of the carrier structure 30. For example, the carrier structure 30 is a package substrate having a core layer and a circuit structure or a coreless circuit structure, and the circuit structure includes at least one insulating layer and at least one circuit layer bonded to the insulating layer. It should be understood that the carrier structure 30 can also be other boards, such as wafers, or other carrier boards having metal routings, but the present disclosure is not limited to as such.

Furthermore, the conductive elements 24 are electrically connected to external pads 301 of the carrier structure 30, and the conductive elements 24 are covered with an underfill 302.

In addition, the carrier structure 30 can be provided with a strengthening member 31 according to requirements, such as a metal frame as shown in FIG. 3, so as to suppress the problem of stress concentration, prevent the carrier structure 30 from warping, and further provide heat dissipation to the electronic package 2.

Therefore, in the manufacturing method of the present disclosure, the photonic integrated circuit chips (the second electronic elements 26) and the switch (the auxiliary electronic element 28) are integrated onto the same package module 2a to shorten the distance between the switch and other optical/electrical signal elements. Therefore, the manufacturing method of the present disclosure can increase the signal transmission rate of the circuit structure 20 and reduce the latency, thereby improving the overall operating performance of the electronic package 2.

Furthermore, the manufacturing method of the present disclosure can be implemented using the existing semiconductor packaging process, so there is no need to develop a special process or purchase equipment with special specifications. Therefore, the manufacturing method of the present disclosure can effectively reduce the production cost of the electronic package 2.

Furthermore, the present disclosure utilizes the design of a silicon bridge (Si Bridge), so that the embedded first electronic elements 21 can electrically bridge the second electronic elements 26 and the auxiliary electronic element 28 to reduce the electrical loss of signal transmission, and high current and/or shielding effects are provided by the plurality of conductive pillars 23 surrounding the first electronic elements 21.

In addition, the auxiliary electronic element 28 and the second electronic element 26 are manufactured separately to reduce the manufacturing difficulty and improve the manufacturing yield. For example, the second electronic element 26 that transmits and receives signals may be damaged due to high temperature under long-term action. Therefore, when the second electronic element 26 is damaged, the second electronic element 26 can be replaced without scrapping the entire package module 2a and the good auxiliary electronic element 28. Therefore, the present disclosure can avoid the problem of wasting materials, thereby reducing the replacement cost at the user end. Furthermore, in other embodiments, the auxiliary electronic element 28 can be a heat dissipation chip to facilitate the dissipation of high heat energy generated by the first electronic elements 21 and the second electronic elements 26 under long-term action. Therefore, damage to the first electronic elements 21 and the second electronic elements 26 can be avoided.

The present disclosure also provides an electronic package 2, which comprises: a cladding layer 25, at least one first electronic element 21, a plurality of conductive pillars 23, a circuit structure 20, at least one auxiliary electronic element 28 and a plurality of second electronic elements 26.

The cladding layer 25 has a first surface 25a, a second surface 25b opposing the first surface 25a, and side surfaces 25c adjacent to the first surface 25a and the second surface 25b.

The first electronic element 21 is embedded in the cladding layer 25, and a plurality of conductors 22 are bonded on and electrically connected to the first electronic element 21, wherein the plurality of conductors 22 are covered by the protective film 211 and embedded in the cladding layer 25, and end surfaces 22a of the plurality of conductors 22 are exposed from the first surface 25a of the cladding layer 25.

The plurality of conductive pillars 23 are embedded in the cladding layer 25, and end surfaces 23a of the plurality of conductive pillars 23 are exposed from the first surface 25a of the cladding layer 25.

The circuit structure 20 is disposed on the first surface 25a of the cladding layer 25 and is electrically connected to the plurality of conductive pillars 23 and the plurality of conductors 22.

The auxiliary electronic element 28 is disposed on the circuit structure 20 and is electrically connected to the circuit structure 20.

The plurality of second electronic elements 26 are disposed on the circuit structure 20 and are electrically connected to the circuit structure 20, wherein the plurality of second electronic elements 26 are photonic integrated circuit chips.

In one embodiment, the first electronic element 21 is surrounded by the plurality of conductive pillars 23.

In one embodiment, the auxiliary electronic element 28 is a switch or a semiconductor chip for heat dissipation.

In one embodiment, the plurality of second electronic elements 26 protrude from the side surfaces 25c of the cladding layer 25.

In one embodiment, the plurality of second electronic elements 26 are connected to electrical connectors 40.

In one embodiment, the electronic package 2 further comprises a circuit portion 240, and the circuit portion 240 is formed on the second surface 25b of the cladding layer 25 and is electrically connected to the plurality of conductive pillars 23. Furthermore, the electronic package 2 may comprise a plurality of conductive elements 24 formed on the circuit portion 240.

In one embodiment, the electronic package 2 further comprises a carrier structure 30 disposed on the second surface 25b of the cladding layer 25.

To sum up, in the electronic package and the manufacturing method thereof of the present disclosure, the photonic integrated circuit chips and the auxiliary electronic element are integrated onto the same package module to shorten the distance between the switch and the optical/electrical signal elements. Therefore, the signal transmission rate of the circuit structure can be increased and the latency can be reduced, thereby improving the overall operating performance of the electronic package.

Furthermore, the manufacturing method of the present disclosure can be implemented using existing semiconductor packaging processes, so there is no need to develop a special process or purchase equipment with special specifications. Therefore, the production cost of the electronic package can be effectively reduced.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. An electronic package, comprising:
a cladding layer having a first surface, a second surface opposing the first surface, and side surfaces adjacent to the first surface and the second surface;
at least one first electronic element embedded in the cladding layer;
a plurality of conductive pillars embedded in the cladding layer;
a circuit structure formed on the first surface of the cladding layer and electrically connected to the plurality of conductive pillars and the at least one first electronic element;
an auxiliary electronic element disposed on and connected to the circuit structure; and
a plurality of second electronic elements disposed on and electrically connected to the circuit structure, wherein the plurality of second electronic elements are photonic integrated circuit chips.

2. The electronic package of claim 1, wherein the at least one first electronic element is bonded and electrically connected to a plurality of conductors.

3. The electronic package of claim 2, wherein the plurality of conductors are covered by a protective film and embedded in the cladding layer, and the plurality of conductors are electrically connected to the circuit structure.

4. The electronic package of claim 1, wherein the at least one first electronic element is surrounded by the plurality of conductive pillars.

5. The electronic package of claim 1, wherein the auxiliary electronic element is a switch or a semiconductor chip for heat dissipation.

6. The electronic package of claim 1, wherein the plurality of second electronic elements protrude from the side surfaces of the cladding layer.

7. The electronic package of claim 1, wherein the plurality of second electronic elements are externally connected to electrical connectors.

8. The electronic package of claim 1, further comprising a circuit portion formed on the second surface of the cladding layer and electrically connected to the plurality of conductive pillars.

9. The electronic package of claim 8, further comprising a plurality of conductive elements formed on the circuit portion.

10. The electronic package of claim 1, further comprising a carrier structure disposed on the second surface of the cladding layer.

11. A method of manufacturing an electronic package, comprising:
disposing a plurality of conductive pillars and at least one first electronic element on a carrier board;
forming a cladding layer on the carrier board to cover the at least one first electronic element and the plurality of conductive pillars, wherein the cladding layer has a first surface and a second surface opposing the first surface, end surfaces of the plurality of conductive pillars are exposed from the first surface of the cladding layer, and the second surface of the cladding layer is bonded onto the carrier board;
forming a circuit structure on the first surface of the cladding layer, wherein the circuit structure is electrically connected to the plurality of conductive pillars and the at least one first electronic element, and the cladding layer is formed with side surfaces adjacent to the first surface and the second surface;
disposing an auxiliary electronic element and a plurality of second electronic elements on the circuit structure, wherein the auxiliary electronic element and the plurality of second electronic elements are connected to the circuit structure, wherein the plurality of second electronic elements are photonic integrated circuit chips; and
removing the carrier board.

12. The method of claim 11, wherein the at least one first electronic element is bonded and electrically connected to a plurality of conductors.

13. The method of claim 12, wherein the plurality of conductors are covered by a protective film and embedded in the cladding layer, and the plurality of conductors are electrically connected to the circuit structure.

14. The method of claim 11, wherein the at least one first electronic element is surrounded by the plurality of conductive pillars.

15. The method of claim 11, wherein the auxiliary electronic element is a switch or a semiconductor chip for heat dissipation.

16. The method of claim 11, wherein the plurality of second electronic elements protrude from the side surfaces of the cladding layer.

17. The method of claim 11, wherein the plurality of second electronic elements are externally connected to electrical connectors.

18. The method of claim 11, further comprising forming a circuit portion on the second surface of the cladding layer, and electrically connecting the circuit portion to the plurality of conductive pillars.

19. The method of claim 18, further comprising forming a plurality of conductive elements on the circuit portion.

20. The method of claim 11, further comprising disposing a carrier structure on the second surface of the cladding layer.
